(19) United States
(12) Patent Application Publication
(10) Pub. No.: US 2004/0150449 A1
(43) Pub. Date: Aug. 5, 2004

(54) High-speed flip-flop circuitry and method for operating the same

(75) Inventors: Christopher M. Durham, Round Rock, TX (US); Hang B. Lauv, Austin, TX (US); Robert T. Golla, Round Rock, TX (US)

Correspondence Address: MARTINE & PENILLA, LLP, 710 LAKEWAY DRIVE, SUITE 170, SUNNYVALE, CA, 94085, US

(73) Assignee: Sun Microsystems, Inc., Santa Clara, CA

(21) Appl. No.: 10/355,651

(22) Filed: Jan. 30, 2003

(51) Int. Cl. H03K 3/289

(52) U.S. Cl. 327/202

(57) ABSTRACT

A high-speed, noise-safe, non-inverting flip-flop (“flop”) is provided. In the flop, a buffer is used to isolate a data input terminal from the remainder of the flop circuitry to prevent erroneous operation of the flop circuitry. Also, a slave node is connected to a master node to avoid the need for an additional buffer on a data signal critical path, thus preserving the high-speed of the flop circuitry. Overlapped clock signals are used to control data signal transmission to the master node and the slave node. The overlapped clock signals allow the buffer used to isolate the data input terminal to also be used to drive the data signal through the master node to the slave node.

### BACKGROUND OF THE INVENTION

1. Field of the Invention

The present invention relates generally to integrated circuits, and more particularly, to a high-speed, noise-safe, non-inverting flip-flop.

2. Description of the Related Art

In digital circuitry, a flip-flop (or “flop”) is a two-state device which offers basic memory for sequential logic operations. Flops are heavily used for digital data storage and transfer and are commonly used in registers for storage of binary numerical data. With a non-inverting flop, the flop receives and stores a data state (“data”) in a first action. Then, in a second action the flop outputs the stored data. The first and second flop actions can be initiated by a clocked digital signal. In this instance, the flop is called a clocked, non-inverting flop.

Traditional clocked, non-inverting flops pass the data input directly through a first transmission gate into a master node upon activation of the first transmission gate. The first transmission gate is activated by a clock signal (e.g., clock going low). The data is stored in the master node in its original state. Also, the data complement is generated by passing the data through a buffer. The data complement is stored in a master complement node. The master complement node is connected to a second transmission gate. Upon activation of the second transmission gate by a clock signal (e.g., clock going high). The data complement is passed through the second transmission gate to a slave node. From the slave node, the data complement is passed through a buffer to regenerate the original data state which is provided as an output signal from the flop.

The traditional, non-inverting flop as previously described is noise sensitive. The noise sensitivity can be described with reference to the data input, the first transmission gate, and the master node. For example, due to capacitive coupling from adjacent circuitry and inductive noise, it is common for a signal from the data input to bounce below ground when coupled signals transition from a high state to a low state while the data input is held low. In some instances the data can bounce significantly below ground exceeding a threshold voltage associated with the first transmission gate. The threshold voltage is generally determined by the process technology. In modern integrated circuitry, the threshold voltages generally range from about 150 mV to about 300 mV. When the threshold voltage of the first transmission gate is exceeded, the master node will be allowed to communicate directly with the data input. Since the data input has bounced below ground, the master node will be pulled to a low state when allowed to communicate with the data input. Therefore, a high state being stored in the master node can be erroneously pulled to a low state when the data input bounces sufficiently below ground to cause the threshold voltage of the first transmission gate to be exceeded. In following, an erroneous master node state will subsequently cause an erroneous flop output.

In view of the foregoing, there is a need for a noise-safe, non-inverting flop apparatus and corresponding method of operation. The noise-safe, non-inverting flop should effectively isolate the noise induced data input bounce from the master node while maintaining high-speed flop performance.

### SUMMARY OF THE INVENTION

Broadly speaking, the present invention fills these needs by providing a noise-safe storage cell. More specifically, the present invention provides a high-speed, noise-safe, clocked, non-inverting flip-flop (“flop”) circuit. In the flop circuit of the present invention, a buffer is used to isolate the data input terminal from the remainder of the flop circuitry to prevent erroneous operation of the flop circuitry. The buffer serves to cancel noise events that cause a signal at the data input terminal to bounce below ground by a magnitude that exceeds a threshold of a transmission gate connected to an output of the buffer. Also, a slave node is connected through a transmission gate to a master node to avoid the need for an additional buffer on a data signal critical path, thus preserving the high-speed of the flop circuitry. The present invention also uses overlapped clock signals to control data signal transmission to the master node and the slave node. The overlapped clock signals allow the buffer used to isolate the data input terminal to also be used to drive the data signal through the master node to the slave node. It should be appreciated that the present invention can be implemented in numerous ways, including as a process, an apparatus, a system, a device, or a method. Several embodiments of the present invention are described below.

In one embodiment, a storage cell is disclosed. The storage cell includes a data port for receiving a data signal in a first state (i.e., either high or low). The storage cell further includes a master cell and a slave cell. The master cell receives the data signal in a second state (i.e., opposite from the first state). The slave cell receives the data signal from the master cell. A clock is also connected to the storage cell. The clock provides the data signal with access to the slave cell from the master cell. A delayed version of the clock provides the data signal with access to the master cell. The clock opens the access to the slave cell from the master cell while the delayed version of the clock allows the access to the master cell to simultaneously remain open. While both the access to the slave cell from the master cell and the access to the master cell are open, the data signal is propagated from the data port through the access to the master cell and through the access to the slave cell from the master cell. The storage cell is further configured to allow the data signal in the second state to be output from the slave cell in the first state.

In another embodiment, a flop circuit is disclosed. The flop circuit includes a data terminal connected to an input of a data buffer. An output of the data buffer is connected to an input of a first transmission gate. An output of the first transmission gate is connected to a master node. An input of a second transmission gate is also connected to the master node. The flop further includes a clock terminal connected to a first set of clock buffers. The first set of clock buffers are configured to control the second transmission gate. A second set of clock buffers are also provided and are connected to the first set of clock buffers. The second set of clock buffers are configured to control the first transmission gate.

In another embodiment, a method for receiving data to be stored and output in a non-inverted state is disclosed. The method includes receiving data in a first state and storing the data in a second state. The data in the second state is stored in both a first storage cell and a second storage cell. The first storage cell and second storage cell are coupled together. Also in the method, a first clock is provided to the second storage cell, and a second clock is provided to the first storage cell. The second clock is a delayed version of the first clock. The method further includes propagating the data from the first storage cell to the second storage cell. To allow for the data propagation, the method includes opening an access to the second storage cell followed by a delayed closing of an access to the first storage cell. The opening of the access to the second storage cell allows the data in the first storage cell to be received in the second storage cell. The data in the second storage cell, which is in the second state, is output from the second storage cell in the first state. Thus, the data is output in a non-inverted state.

In another embodiment, a method for operating a flop is disclosed. The method includes receiving a clock signal and a data signal. The data signal is buffered to provide the effect of isolating the buffered data signal from the original data signal. The method further includes opening a first transmission gate upon receipt of a clock signal. Opening of the first transmission gate causes the buffered data signal to be transmitted to a master node. The method also includes closing a second transmission gate upon receipt of the clock signal. When the clock signal begins to change, the second transmission gate is opened to cause a state of the master node to be transmitted to a slave node. Also, when the clock signal begins to change, closure of the first transmission gate is delayed. The delayed closure of the first transmission gate causes the buffered data signal to continue to be transmitted through the first transmission gate to the master node and through the second transmission gate to the slave node. When the clock signal is changed, the first transmission gate is closed, and the master node holds its current state.

Other aspects of the invention will become more apparent from the following detailed description, taken in conjunction with the accompanying drawings, illustrating by way of example the present invention.

### BRIEF DESCRIPTION OF THE DRAWINGS

The invention, together with further advantages thereof, may best be understood by reference to the following description taken in conjunction with the accompanying drawings in which:

FIG. 1 is an illustration showing a block diagram of the flop, in accordance with one embodiment of the present invention;

FIG. 2 is an illustration showing the flop circuitry, in accordance with one embodiment of the present invention;

FIG. 3 is an illustration showing waveforms associated with operation of the flop, in accordance with one embodiment of the present invention; and

FIG. 4 shows a flowchart illustrating a method for flop circuit operation, in accordance with one embodiment of the present invention.

### DETAILED DESCRIPTION OF THE PREFERRED EMBODIMENTS

Broadly speaking, an invention is disclosed for an apparatus and a method of operation for a noise-safe storage cell capable of storing a data state. More specifically, the present invention provides a high-speed, noise-safe, clocked, non-inverting flip-flop circuit (“flop”). In the flop of the present invention, a buffer is used to isolate a data input terminal from a remainder of the flop circuitry to prevent erroneous operation of the flop circuitry. The buffer serves to cancel noise events that cause a signal at the data input terminal to bounce below ground by a magnitude that exceeds a threshold of a transmission gate connected to an output of the buffer. Also, in the flop of the present invention, a slave node is connected through a transmission gate to a master node to avoid the need for an additional buffer on a data signal critical path, thus preserving the high-speed of the flop. The flop of the present invention also uses overlapped clock signals to control data signal transmission to the master node and the slave node. The overlapped clock signals allow the buffer used to isolate the data input terminal to also be used to drive the data signal through the master node to the slave node. It should be appreciated that the present invention can be implemented in numerous ways, including as a process, an apparatus, a system, a device, or a method. Several exemplary embodiments of the invention will now be described in detail with reference to the accompanying drawings.

In the following description, numerous specific details are set forth in order to provide a thorough understanding of the present invention. It will be apparent, however, to one skilled in the art that the present invention may be practiced without some or all of these specific details. In other instances, well known process operations have not been described in detail in order not to unnecessarily obscure the present invention.

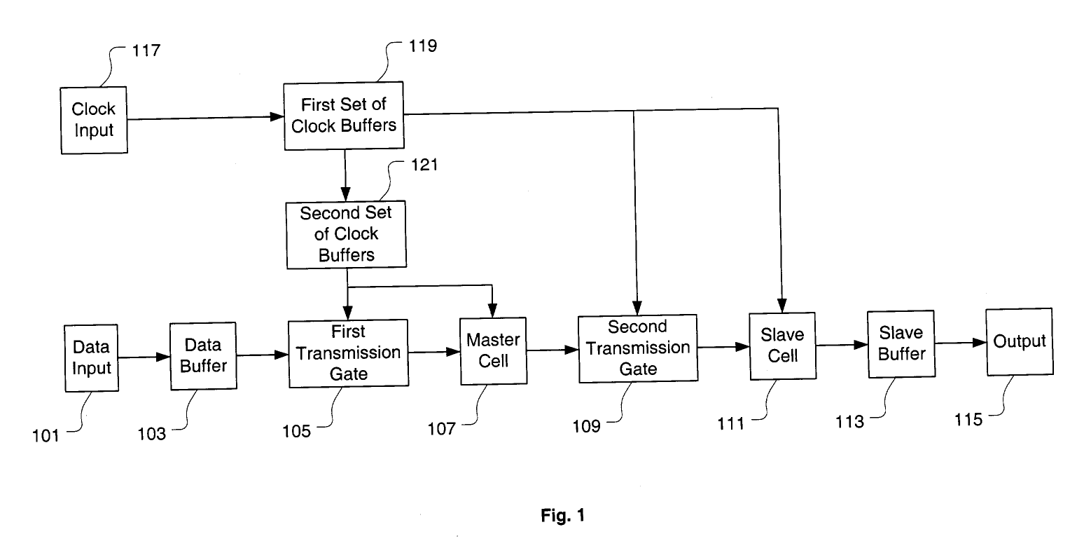

FIG. 1 is an illustration showing a block diagram of the flop, in accordance with one embodiment of the present invention. The block diagram of the flop provides a high-level representation of the flop to facilitate presentation of the overall flop layout and functionality. The flop is configured to receive a data input 101. The data input 101 is transmitted through a data buffer 103. The data buffer 103 causes the data input 101 to be inverted to an opposite state. For example, if the data input 101 is a high signal, the output from the data buffer 103 will be a low signal, vice-versa. The data buffer 103 is configured to communicate electrically with a first transmission gate 105. In this manner, the data buffer 103 also acts to isolate the first transmission gate 105 from the data input 101. Therefore, any signal bounce at the data input 101 will not affect the operation of the first transmission gate 105. For example, if capacitive coupling or inductance noise causes the data input 101 to bounce below ground sufficiently to exceed a threshold voltage of the first transmission gate 105, the data buffer 103 will shield the first transmission gate 105 from the data input 101 bounce. Thus, the data buffer 103 will ensure that the transmission gate 105 in a closed condition will remain in a closed condition.

The first transmission gate 105 controls a signal flow from the data buffer 103 to a master cell 107. When the first transmission gate 105 is in a closed condition, the signal is not allowed to flow from the data buffer 103 to the master cell 107. Conversely, when the first transmission gate 105 is in an open condition, the signal is allowed to flow from the data buffer 103 to the master cell 107. The master cell 107 is configured to store and maintain a signal state. The master cell 107 includes feedback circuitry for maintaining the signal state existing in the master cell 107.

A second transmission gate 109 is disposed between the master cell 107 and a slave cell 111. The second transmission gate 109 controls a signal flow from the master cell 107 to the slave cell 111. When the second transmission gate 109 is in a closed condition, the signal is not allowed to flow from the master cell 107 to the slave cell 111. Conversely, when the second transmission gate 109 is in an open condition, the signal is allowed to flow from the master cell 107 to the slave cell 111. The condition of the second transmission gate 109 is controlled to be opposite the condition of the first transmission gate 105. The slave cell 111 is configured to store and maintain a signal state. The slave cell 111 includes feedback circuitry for maintaining the signal state existing in the slave cell 111.

The signal state stored in the slave cell 111 is transmitted through a slave buffer 113. The slave buffer 113 causes the signal state stored in the slave cell 111 to be inverted to an opposite state. For example, if the signal state stored in the slave cell 111 is a high signal, the output from the slave buffer 113 will be a low signal, vice-versa. Therefore, the slave buffer 113, in part, serves to un-invert the signal state as previously inverted by the data buffer 103. The signal output from the slave buffer 113 is transmitted to a flop output 115. Therefore, the signal state at the flop output 115 matches the signal state provided at the data input 101. Thus, the flop is non-inverting.

The flop is further configured to receive a clock input 117. The clock input 117 is used to control the condition of the first transmission gate 105 and the second transmission gate 109. The clock input 117 is also used to control the feedback circuitry in both the master cell 107 and the slave cell 111. The clock input 117 is transmitted through a first set of clock buffers 119 to generate a first set of clock signals. The first set of clock signals are transmitted to the second transmission gate 109 and the slave cell 111. The first set of clock signals are also transmitted through a second set of clock buffers 121. The second set of clock buffers 121 generate a second set of clock signals. The second set of clock signals are transmitted to the first transmission gate 105 and the master cell 107. Since the second set of clock signals are generated by passing the first set of clock signals through the second set of clock buffers 121, the second set of clock signals are delayed with respect to the first set of clock signals. The delay between the second set of clock signals and the first set of clock signals is called an overlapping clock delay. The overlapping clock delay is important to the functionality of the flop.

Consider the situation in which the first transmission gate 105 is open and the second transmission gate 109 is closed. The first set of clock signals are transmitted to the second transmission gate 109 to instruct the second transmission gate 109 to open. The second set of clock signals are transmitted to the first transmission gate 105 to instruct the first transmission gate 105 to close. However, due to the overlapping clock delay, the first set of clock signals will arrive at the second transmission gate 109 before the second set of clock signals arrive at the first transmission gate 105. Therefore, the second transmission gate 109 will open before the first transmission gate 105 closes, resulting in an instance in which both the first transmission gate 105 and the second transmission gate 109 are open. During the instance when both the first transmission gate 105 and the second transmission gate 109 are open, the signal from the data buffer 103 is transmitted through the first transmission gate 105 to the master cell 107 and on through the second transmission gate 109 to the slave cell 111. A sufficiently strong data buffer 103 is provided to push the signal from the data buffer 103 to the slave cell 111 during this instance.

The operation of the flop of the present invention can be described as follows. Consider the situation when the clock input is low. When the clock input is low, the first transmission gate 105 is in an open condition and the signal from the data buffer 103 is being transmitted through the first transmission gate 105 to the master cell 107. Also, when the clock input is low, the second transmission gate 109 is in a closed condition and the feedback circuitry of the slave cell 111 is on to maintain the signal state stored in the slave cell 111. When the clock input begins to go high, the second transmission gate 109 will transition to an open condition and the feedback circuitry of the slave cell 111 will be turned off. Due to the overlapping clock delay, when the clock input begins to go high, the first transmission gate 105 will remain in the open condition for an instance. During this instance the signal from the data buffer 103 is being transmitted through the first transmission gate 105 to the master cell 107 and on through the second transmission gate 109 to the slave cell 111. When the clock input goes high and the overlapping clock delay has passed, the first transmission gate 105 will be in a closed condition and the feedback circuitry of the master cell 107 will be on to maintain the signal state stored in the master cell 107. At this point, the signal state stored in the master cell 107 is being transmitted through the second transmission gate 109 to the slave cell 111. When the clock input goes low, the second transmission gate 109 transitions to a closed condition and the feedback circuitry of the slave cell 111 turns on. Then, following the overlapping clock delay, the first transmission gate 105 transitions to an open condition and the feedback circuitry of the master cell 107 turns off. The operation of the flop then repeats as described from the beginning of this paragraph. During the flop operation, the data input is continuously provided to the data buffer 103. The data input can be changed arbitrarily and independently from the flop operation. Also, during the flop operation, the slave buffer 113 is inverting and transmitting the signal state continuously received from the slave cell 111 to the output 115.

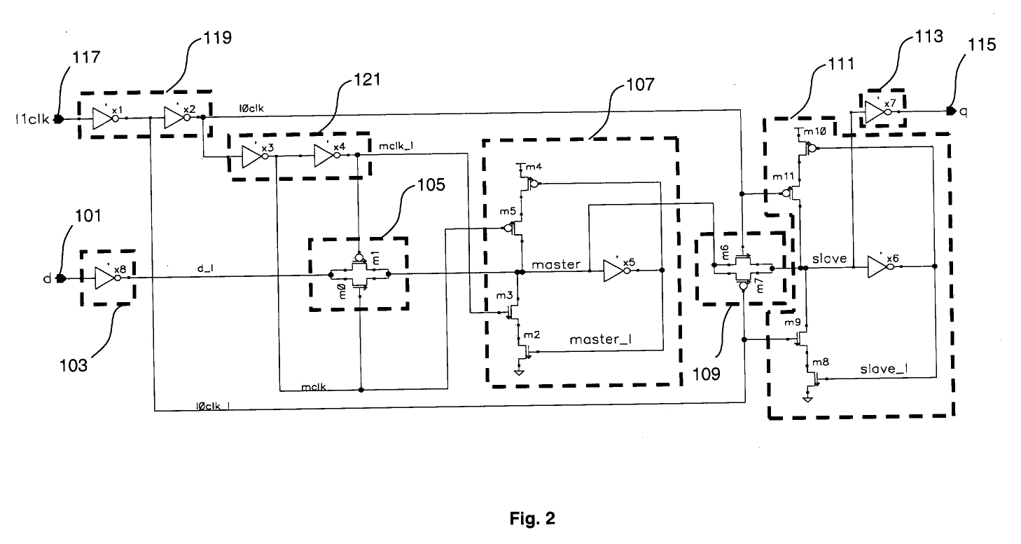

FIG. 2 is an illustration showing the flop circuitry, in accordance with one embodiment of the present invention. The flop circuitry includes a data input terminal d for receiving the data input 101. The data buffer 103 is represented as an inverter x8. The inverter x8 receives the data signal from the data input terminal d. The inverter x8 generates a signal d_1 which is a complement of the data signal. The signal d_1 is transmitted to an input of the first transmission gate 105. At the input of the first transmission gate 105, the signal d_1 is received by both a PMOS device m1 and an NMOS device m0. As previously discussed, the NMOS device m0 and the PMOS device m1 are controlled by the second set of clock signals mclk and mclk_1 generated by inverters x3 and x4, respectively, which together constitute the second set of clock buffers 121. When NMOS device m0 and PMOS device m1 are turned on, the signal d_1 is transmitted through to a master node contained within the master cell 107.

The master cell 107 includes feedback circuitry having inverter x5, PMOS devices m4 and m5, and NMOS devices m2 and m3. The inverter x5 is used to invert the signal d_1 to generate a control signal master_{—1} for PMOS device m4 and NMOS device m2. Thus, PMOS device m4 is used to maintain a high master node state, and NMOS device m2 is used to maintain a low master node state. The feedback through PMOS device m4, however, is controlled by PMOS device m5 which is controlled by the mclk signal received from inverter x3 in the second set of clock buffers 121. Similarly, the feedback through NMOS device m2 is controlled by NMOS device m3 which is controlled by the mclk_1 signal received from inverter x4 in the second set of clock buffers 121. When NMOS device m0 and PMOS device m1 are on, NMOS device m3 and PMOS device m5 are off. Thus, when the first transmission gate 105 is in an open condition, the feedback circuitry of the master cell 107 is off, vice-versa.

The signal d_{—1} stored in the master node of the master cell 107 is transmitted to an input of the second transmission gate 109. At the input of the second transmission gate 109, the signal d_1 is received by both a PMOS device m7 and an NMOS device m6. As previously discussed, the NMOS device m6 and the PMOS device m7 are controlled by the first set of clock signals 10clk and 10clk_1 generated by inverters x2 and x1, respectively, which together constitute the first set of clock buffers 119. The inverter x1 in the first set of clock buffers 119 receives the clock input 117 from a clock terminal 11clk. When NMOS device m6 and PMOS device m7 are turned on, the signal d_1 is transmitted through to a slave node contained within the slave cell 111.

The slave cell 111 includes feedback circuitry having inverter x6, PMOS devices m10 and m11, and NMOS devices m8 and m9. The inverter x6 is used to invert the signal d_1 to generate a control signal slave_{—1} for PMOS device m10 and NMOS device m8. Thus, PMOS device m10 is used to maintain a high slave node state, and NMOS device m8 is used to maintain a low slave node state. The feedback through PMOS device m10, however, is controlled by PMOS device m11 which is controlled by the 10clk signal received from inverter x2 in the first set of clock buffers 119. Similarly, the feedback through NMOS device m8 is controlled by NMOS device m9 which is controlled by the 10clk_1 signal received from inverter x1 in the first set of clock buffers 119. When NMOS device m6 and PMOS device m7 are on, NMOS device m9 and PMOS device m11 are off. Thus, when the second transmission gate 109 is in an open condition, the feedback circuitry of the slave cell 111 is off, vice-versa.

The signal d_{—1} stored on the slave node is transmitted to the slave buffer 113. The slave buffer 113 is represented as an inverter x7. The inverter x7 re-generates the original data input 101 by generating a complement of the signal d_1. The original data input 101 is transmitted to the output 115 which is represented as an output terminal q.

It is important to note that the overlapping clock delay, as provided by inverters x3 and x4 relative to inverters x1 and x2, allows the inverter x8 to push the signal d_1 through the flop to the inverter x7 on a rising edge of clock input 11clk. The inverter x8 is, therefore, sized appropriately to provide sufficient drive to transmit the signal d_1 through the flop. Without the overlapping clock signals, the signal stored on the master node would have to be driven to the inverter x7 by the PMOS devices m4 and m5 and the NMOS devices m2 and m3. The PMOS devices m4 and m5 and the NMOS devices m2 and m3 would have to be increased in size by about a factor of 10 to provide sufficient drive for transmitting the signal from the master node to inverter x7. Also, a load on the clock input 117 would be prohibitively large if the PMOS devices m4 and m5 and the NMOS devices m2 and m3 were increased in size by about a factor of 10. Furthermore, substantially increasing the sizes of PMOS device m4 and NMOS device m2 will increase a critical path delay because PMOS device m4 and NMOS device m2 must be driven by inverter x5, which is driven by inverter x8. Also, substantially increasing the sizes of PMOS device m5 and NMOS device m3 will increase the capacitive load on the master node, causing the flop to be slowed considerably. Therefore, the overlapping clock delay as provided by the present invention is an important aspect of the flop implementation and functionality.

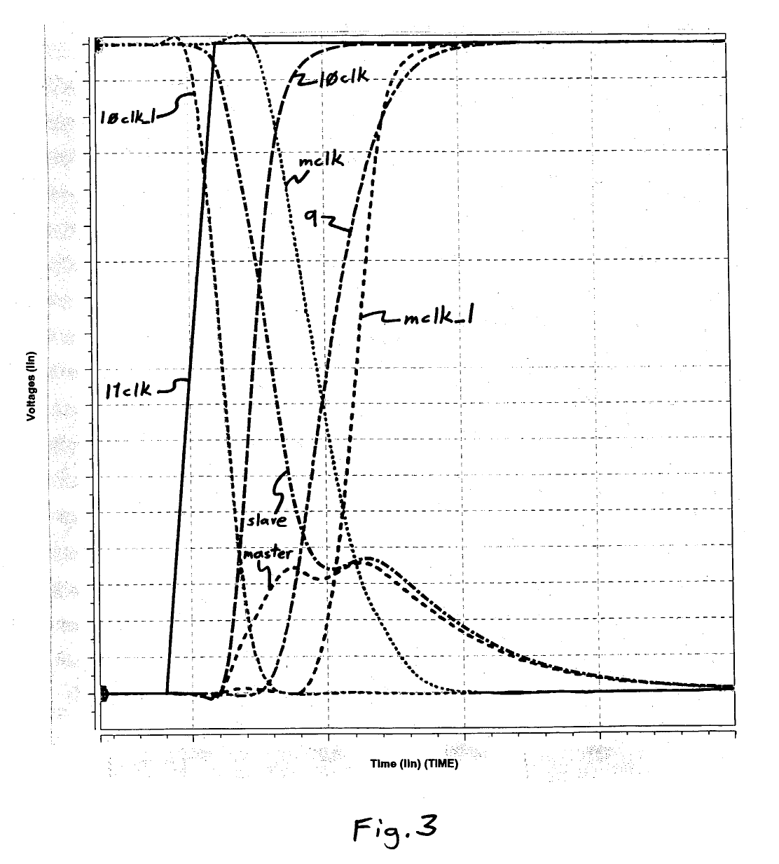

FIG. 3 is an illustration showing waveforms associated with operation of the flop, in accordance with one embodiment of the present invention. Waveforms are shown for the signals 10clk_1 and 10clk exiting inverters x1 and x2, respectively, in the first set of clock buffers 119. Also, waveforms are shown for the signals mclk and mclk_1 exiting inverters x3 and x4, respectively, in the second set of clock buffers 121. Waveforms of the signals present at the clock terminal 11clk, the master node, the slave node, and the output terminal q are also shown. The waveforms shown in FIG. 3 correspond to a rising edge of the clock input 117. Observation of the 10clk_1 and 10clk waveforms relative to the mclk and mclk_1 waveforms illustrate the overlapping clock delay as previously discussed. The corresponding effect of the overlapping clock delay on the signals present at the master node, slave node, and output terminal are also illustrated.

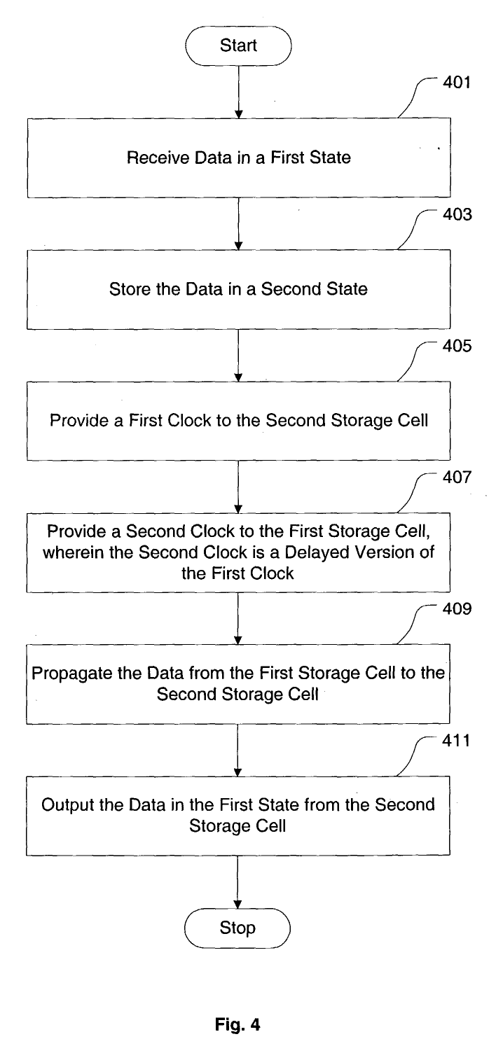

FIG. 4 shows a flowchart illustrating a method for flop circuit operation, in accordance with one embodiment of the present invention. The method includes an operation 401 in which the flop receives data in a first state. In an operation 403, the data is stored in a second state. The second state can be obtained by buffering the data received in the first state, wherein the buffering causes the first state to be inverted. The data in the second state is stored in a first storage cell and a second storage cell, wherein the first and second storage cells are coupled together. In one embodiment, the first storage cell can be a master cell and the second storage cell can be a slave cell. The method further includes an operation 405 in which a first clock is provided to the second storage cell. The method continues with an operation 407 in which a second clock is provided to the first storage cell. The second clock is a delayed version of the first clock. In one embodiment, the second clock is delayed relative to the first clock by passing the first clock through a number of buffers to generate the second clock. In an operation 409, the data stored in the first storage cell is propagated to the second storage cell. The data propagation is facilitated by an access to the second storage cell opening to receive the data from the first storage cell. In one embodiment, the access to the second storage cell is controlled by the first clock. The data propagation is further facilitated by delaying a closure of an access to the first storage cell, through which the data was initially received in the second state. In one embodiment, the access to the first storage cell is controlled by the second clock which is the delayed version of the first clock used to control the access to the second storage cell. The method further includes an operation 411 in which the data in the second state that is contained in the second storage cell is output from the second storage cell in the first state. In one embodiment, the data output in the first state can be obtained by buffering the data in the second state that is contained in the second storage cell, wherein the buffering causes the second state to be inverted.

While this invention has been described in terms of several embodiments, it will be appreciated that those skilled in the art upon reading the preceding specifications and studying the drawings will realize various alterations, additions, permutations and equivalents thereof. It is therefore intended that the present invention includes all such alterations, additions, permutations, and equivalents as fall within the true spirit and scope of the invention.

What is claimed is:

1. A storage cell, comprising:
a data port for receiving data having a first state;
a master cell for receiving the data in a second state;
a slave cell for receiving the data from the master cell; and
a clock being connected to provide access to the slave cell, and the clock having a buffered delay connection to provide access to the master cell, wherein the data is propagated from the data port through the access to the master cell and through the access to the slave cell, the access to the slave cell opening to receive the data in the slave cell from the master cell followed by a delayed closing of the access to the master cell,
wherein the data in the second state is output from the slave cell in the first state.

2. A storage cell as recited in claim 1, further comprising a buffer for converting the data received from the data port in the first state to the data in the second state received by the master cell.

3. A storage cell as recited in claim 1, wherein the access to the slave cell is controlled by a transmission gate connected to the clock.

4. A storage cell as recited in claim 1, wherein the access to the master cell is controlled by a transmission gate connected to the clock through the buffered delay connection.

5. A storage cell as recited in claim 1, wherein the slave cell is connected directly to the master cell.

6. A flop circuit, comprising:
a data terminal;
a data buffer having an input and an output, the input being in electrical communication with the data terminal;
a first transmission gate having an input and an output, the input being in electrical communication with the output of the data buffer;
a master node in electrical communication with the output of the first transmission gate;
a second transmission gate having an input and an output, the input being in electrical communication with the master node;
a clock terminal;
a first set of clock buffers in electrical communication with the clock terminal, the first set of clock buffers configured to control the second transmission gate; and
a second set of clock buffers in electrical communication with the first set of clock buffers, the second set of clock buffers configured to control the first transmission gate.

7. A flop circuit as recited in claim 6, wherein the output from the second set of clock buffers is delayed relative to the output from the first set of clock buffers.

8. A flop circuit as recited in claim 7, wherein the delayed output from the second set of clock buffers allows the second transmission gate to open before the first transmission gate is closed, wherein an instance exists when both the first transmission gate and the second transmission gate are open.

9. A flop circuit as recited in claim 8, wherein the data buffer is configured to drive a signal through the first transmission gate, the master node, and the second transmission gate at the instance.

10. A flop circuit as recited in claim 6, wherein both the first set of clock buffers and the second set of clock buffers each comprise:
a first buffer having an input and an output; and
a second buffer having an input and an output, the input of the second buffer being connected with the output of the first buffer.

11. A flop circuit as recited in claim 10, wherein the input of first buffer in the second set of clock buffers is in electrical communication with the output of the second buffer in first set of clock buffers.

12. A flop circuit as recited in claim 6, further comprising:
master node feedback circuitry, the master node feedback circuitry being configured to maintain a state of the master node, the master node feedback circuitry being further configured to be controlled by the second set of clock buffers.

13. A flop circuit as recited in claim 6, further comprising:
a slave node in electrical communication with the output of the second transmission gate;
a slave buffer having an input and an output, the input of the slave buffer being in electrical communication with the slave node; and
an output terminal in electrical communication with the output of the slave buffer.

14. A flop circuit as recited in claim 13, further comprising:
slave node feedback circuitry, the slave node feedback circuitry being configured to maintain a state of the slave node, the slave node feedback circuitry being further configured to be controlled by the first set of clock buffers.

15. A method for receiving data to be stored and output in a non-inverted state, comprising:
receiving data in a first state;
storing the data in a second state in a first storage cell and a second storage cell, the first storage cell being coupled to the second storage cell;
providing a first clock to the second storage cell;
providing a second clock to the first storage cell, the second clock being a delayed version of the first clock; and
propagating the data from the first storage cell to the second storage cell, an access to the second storage cell opening to receive the data in the second storage cell from the first storage cell followed by a delayed closing of an access to the first storage cell, the data in the second state is output from the second storage cell in the first state.

16. A method for receiving data to be stored and output in a non-inverted state as recited in claim 15, wherein the second clock is delayed relative to the first clock by passing the first clock through a number of buffers to generate the second clock.

17. A method for receiving data to be stored and output in a non-inverted state as recited in claim 15, wherein the access to the second storage cell is controlled by the first clock.

18. A method for receiving data to be stored and output in a non-inverted state as recited in claim 15, wherein the access to the first storage cell is controlled by the second clock.

19. A method for receiving data to be stored and output in a non-inverted state as recited in claim 15, further comprising:
buffering the data received in the first state to generate the data in the second state.

20. A method for receiving data to be stored and output in a non-inverted state as recited in claim 15, further comprising:
buffering the data in the second state stored in the second storage cell to generate the data in the first state output from the second storage cell.

21. A method for operating a flop, comprising:
receiving a clock signal;
receiving a data signal;
buffering the data signal, the buffered data signal being isolated from the data signal;
opening a first transmission gate upon receipt of the clock signal, the opening of the first transmission gate causing the buffered data signal to be transmitted to a master node;
closing a second transmission gate upon receipt of the clock signal;
opening the second transmission gate when the clock signal begins to change, the opening of the second transmission gate causing a state of the master node to be transmitted to the slave node;
delaying a closing of the first transmission gate when the clock signal begins to change, the delaying causing the buffered data signal to continue to be transmitted to the master node, the buffered data signal being transmitted through the master node to the slave node; and
closing the first transmission gate when the clock signal is changed, the closing of the first transmission gate causing the master node to hold a state.

22. A method for operating a flop as recited in claim 21, further comprising:
buffering the clock signal to provide control signals for opening and closing the second transmission gate; and
re-buffering the clock signal to provide control signals for opening and closing the first transmission gate, the re-buffering causing the delaying of the closing of the first transmission gate when the clock signal begins to change.

23. A method for operating a flop as recited in claim 22, further comprising:
using the control signals from the buffered clock signal to activate slave node feedback circuitry, activation of the slave node feedback circuitry causing the slave node to hold a state.

24. A method for operating a flop as recited in claim 22, further comprising:
using the control signals from the re-buffered clock signal to activate master node feedback circuitry, activation of the master node feedback circuitry causing the master node to hold a state.

25. A method for operating a flop as recited in claim 21, further comprising:
inverting a state of the slave node with a buffer, the inverted state of the slave node corresponding to a state of the received data signal; and
transmitting the inverted state of the slave node to an output terminal.
